(19) United States
(12) Patent Application Publication
(10) Pub. No.: US 2014/0159264 A1
(43) Pub. Date: Jun. 12, 2014

(54) SOLUTION OF AROMATIC POLYAMIDE FOR PRODUCING DISPLAY ELEMENT, OPTICAL ELEMENT, OR ILLUMINATION ELEMENT

(71) Applicants: SUMITOMO BAKELITE CO., LTD., SHINAGAWA-KU (JP); AKRON POLYMER SYSTEMS, INC., AKRON, OH (US)

(72) Inventors: Frank W. HARRIS, BOCA RATON, FL (US); DONG ZHANG, UNIONTOWN, OH (US); LIMIN SUN, COPLEY, OH (US); JIAOKAI JING, UNIONTOWN, OH (US); TOSHIMASA EGUCHI, KOBE-SHI (JP); HIDEO UMEDA, KOBE-SHI (JP); RITSUYA KAWASAKI, KOBE-SHI (JP); JUN OKADA, KOBE-SHI (JP); MIZUHO INOUE, KOBE-SHI (JP)

(73) Assignees: SUMITOMO BAKELITE CO., LTD., SHINAGAWA-KU (JP); AKRON POLYMER SYSTEMS, INC., AKRON, OH (US)

(21) Appl. No.: 14/097,806

(22) Filed: Dec. 5, 2013

Related U.S. Application Data
(60) Provisional application No. 61/734,614, filed on Dec. 7, 2012.

(51) Int. Cl. C08K 5/544; H01L 27/32; H01L 51/00

(52) U.S. Cl. CPC C08K 5/544; H01L 51/0097; H01L 27/3244
USPC 264/21; 524/726

(57) ABSTRACT

This disclosure, viewed from one aspect, this disclosure relates to a solution of polyamide comprising: an aromatic polyamide, a silane coupling agent and a solvent. The solution of polyamide can improve adhesion between the polyamide film and the base of glass or silicon wafer.

### CROSS REFERENCE TO RELATED APPLICATIONS

The disclosure is based upon and claims priority from U.S. Provisional Application Ser. No. 61/734,614, the disclosure of which is hereby incorporated by reference herein in its entirety.

### TECHNICAL FIELD

This disclosure, in one aspect, relates to a solution of polyamide including an aromatic copolyamide, a solvent and a silane coupling agent. This disclosure, in another aspect, relates to a process of manufacturing the polyamide solution. This disclosure, in another aspect, relates to a process for manufacturing a display element, an optical element or an illumination element, including a step of forming a polyamide film using the polyamide solution.

### BACKGROUND

Organic Light Emitting Diode (OLED) displays were a $1.25 billion market in 2010, which is projected to grow annually at a rate of 25%. The high efficiency and high contrast ratio of OLED displays make them a suitable replacement for liquid crystal displays (LCDs) in the mobile phone display, digital camera, and global positioning system (GPS) market segments. These applications place a premium on high electrical efficiency, compact size, and robustness. This has increased the demand for active matrix OLEDs (AMOLEDs) which consume less power, have faster response times, and higher resolutions. AMOLED innovations that improve these properties will further accelerate AMOLED adoption into portable devices and expand the range of devices that use them. These performance factors are largely driven by the processing temperature of the electronics. AMOLEDs have a thin-film transistor (TFT) array structure which is deposited on the transparent substrate. Higher TFT deposition temperatures can dramatically improve the electrical efficiency of the display. Currently, glass plates are used as AMOLED substrates. They offer high processing temperatures (>500° C.) and good barrier properties, but are relatively thick, heavy, rigid, and are vulnerable to breaking, which reduces product design freedom and display robustness. Thus, there is a demand by portable device manufacturers for a lighter, thinner, and more robust replacement. Flexible substrate materials would also open new possibilities for product design, and enable lower cost roll-to-roll fabrication.

Many polymer thin films have excellent flexibility, transparency, are relatively inexpensive, and are lightweight. Polymer films are excellent candidates for substrates for flexible electronic devices, including flexible displays and flexible solar cell panels, which are currently under development. Compared to rigid substrates like glass, flexible substrates offer some potentially significant advantages in electronic devices, including:
a. Light weight (glass substrates represent about 98% of the total weight in a thin film solar cell).
b. Flexible (Easy to handle, low transportation costs, and/or more applications for both raw materials and products.)
c. Amenable to roll-to-roll manufacturing, which could greatly reduce the manufacturing costs.

To facilitate these inherent advantages of a polymeric substrate for the flexible display application, several issues must be addressed including:
a. Increasing the thermal stability;
b. Reducing the coefficient of thermal expansion (CTE);
c. Maintaining high transparency during high temperature processing; and,
   Increasing the oxygen and moisture barrier properties. Currently, no pure polymer film can provide sufficient barrier properties. To achieve the target barrier property, an additional bather layer must be applied.

Several polymer films have been evaluated as transparent flexible substrates, including: polyethylene terephthalate (PET), polyethylene naphthalate (PEN), polycarbonate (PC), polyethersulfone (PES), cyclic olefin polymer (COP), polyarylates (PAR), polyimides (PI), and others. However, no one film can meet all the requirements. Currently, the industrial standard for this application is PEN film, which meets part of the requirements (Transmittance >80% between 400 nm˜750 nm, CTE<20 ppm/° C.), but has a limited use temperature (<200° C.). A transparent polymer film with a higher thermal stability (T_{g}>300° C.) and a lower CTE (<20 ppm/° C.) is desirable.

Conventional aromatic polyimides are well known for their excellent thermal and mechanical properties, but their films, which must be cast from their polyamic acid precursors, are usually dark yellow to orange. Some aromatic polyimides have been prepared that can be solution cast into films that are colorless in the visible region, but such films do not display the required low CTE (For example, F. Li. F. W. Harris, and S. Z. D. Cheng, Polymer, 37, 23, pp 5321 1996). The films are also not solvent resistant. Polyimide films based on part or all alicyclic monomers, such as those described in patents JP 2007-063417 and JP 2007-231224, and publication by A. S. Mathews et al (J. Appl. Polym. Sci., Vol. 102, 3316-3326, 2006), show improved transparency. Although T_{g}s of these polymers can be higher than 300° C., at these temperatures the polymers do not show sufficient thermal stability due to their aliphatic units.

Although most aromatic polyamides are poorly soluble in organic solvents and cannot be solution cast into films, a few polymers have been prepared that are soluble in polar aprotic solvents containing inorganic salts. Some of these have been investigated for use as flexible substrates. For example, JP 2009-79210A describes a thin film prepared from a fluorine containing aromatic polyamide that displays a very low CTE (<0 ppm/° C.), good transparency (T %>80 between 450˜700 nm), and excellent mechanical properties. However, the maximum thickness of films made from this polymer is 20 μm, because a dry-wet method where the salt is removed must be used for the film preparation. Most importantly, the film also displays poor resistance to strong organic solvents.

WO 2012/129422 discloses a solvent resistant copolyamide film and a method of the film.

### SUMMARY

This disclosure, in one aspect, relates to a solution of polyamide comprising: an aromatic polyamide, a silane coupling agent and a solvent.

This disclosure, in another aspect, relates to a process for manufacturing a solution of an aromatic polyamide comprising the steps of:

a) dissolving at least one aromatic diamine in a solvent;

b) reacting the at least one aromatic diamine mixture with at least one aromatic diacid dichloride, wherein hydrochloric acid and a polyamide solution are generated;

c) removing the free hydrochloric acid by reaction with a trapping reagent;

d) adding a silane coupling agent.

This disclosure, in another aspect, relates to a process for manufacturing a display element, an optical element or an illumination element, comprising the steps of:

a) dissolving at least one aromatic diamine in a solvent;

b) reacting the at least one aromatic diamine mixture with at least one aromatic diacid dichloride, wherein hydrochloric acid and a polyamide solution are generated;

c) removing the free hydrochloric acid by reaction with a trapping reagent;

d) adding a silane coupling agent.

e) casting the resulting polyamide solution onto a base to form a polyamide film, wherein the base or the surface of the base is composed of glass or silicon wafer;

f) forming the display element, the optical element or the illumination element on the surface of the polyamide film.

This disclosure, in another aspect, relates to a process for manufacturing a display element, an optical element or an illumination element, comprising the steps of:

a) casting a solution of an aromatic polyamide into a film onto a base; and

b) forming the display element, the optical element or the illumination element on the surface of polyamide film;

wherein the solution of an aromatic polyamide comprising an aromatic polyamide, a solvent, and a silane coupling agent,

wherein the base or the surface of the base is composed of glass or silicon wafer.

### BRIEF DESCRIPTION OF THE DRAWINGS

FIG. 1 is a schematic cross-sectional view showing an organic EL element 1 according to one embodiment.

FIG. 2 is a classification table of adhesion tape test.

FIG. 3 is a schematic flow of a manufacturing process of OLED element.

### DETAILED DESCRIPTION

A display element, an optical element, or an illumination element such as an organic electro-luminescence (OEL) or organic light-emitting diode (OLED) is often produced by the process described in FIG. 3. Briefly, a polymer solution (varnish) is applied or casted onto a glass base or a silicon wafer base (step A), the applied polymer solution is cured to form a film (step B), an element such as OLED is formed on the film (step C), and then, the element such as OLED (product) is de-bonded from the base (step D). These days, polyimide film is used as the film in the process in FIG. 3. It is discovered that when a polyamide film is used as the film in the process in FIG. 3, weakness of adhesion between the film and the base becomes problematic. Specifically, weakness of adhesion between a polyamide film and a glass or silicon wafer base cause a low yield rate of the product and a difficulty of handling in the step C. It is further discovered that when a polyamide solution containing a silane coupling agent used as the varnish, adhesion between the film and the base significantly improved.

Therefore, viewed from one aspect, this disclosure relates to a solution of polyamide comprising: an aromatic polyamide, silane coupling agent and a solvent (hereinafter, referred also to as “the solution of the present disclosure”).

In one or plurality of embodiments of this disclosure, the solution of the present disclosure is used in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film,

wherein the base or the surface of the base is composed of glass or silicon wafer.

In one or plurality of embodiments of this disclosure, the silane coupling agent has an amino group and/or an epoxy group, in terms of enhancement of the adhesion between polyamide film and the base, and reducing the amount of the silane coupling agent to be added. In one or plurality of embodiments of this disclosure, the silane coupling agent preferably has a methoxy and/or ethoxy group, in terms of enhancement of the adhesion between polyamide film and the base. In one or plurality of embodiments of this disclosure, the silane coupling agent includes, but is not limited to, Trimethoxy[2-(7-oxabicyclo[4.1.0]hept-3-yl)ethyl]silane, 3-Glycidoxypropylethyldimethoxysilane, 3-Glycidoxypropyltrimethoxysilane, 3-Glycidoxypropylmethyldiethoxysilane, 3-Glycidoxypropyltriethoxysilane, 3-(2-Aminoethylamino)propyl-dimethoxymethylsilane, 3-(2-Aminoethylamino)propyl-trimethoxysilane, 3-(Trimethoxysilyl)-1-propanamine, 3-(Triethoxysilyl)-1-propanamine, 3-triethoxysilyl-N-(1,3-dimethyl-butylidene)propylamine), N-[3-(Trimethoxysilyl)propyl]aniline, in terms of enhancement of the adhesion between polyamide film and the base.

In one or plurality of embodiments of this disclosure, concentration of silane coupling agent in the solution is, but is not limited to, 0.001 parts per hundred resins of polyamide (phr) or more, 0.01 phr or more, 0.1 phr or more, 0.3 phr or more, 0.4 phr or more, or 0.5 phr or more.
In one or plurality of embodiments of this disclosure, concentration of silane coupling agent in the solution is, but is not limited to, 10.0 parts per hundred resins of polyamide (phr) or less, 5.0 phr or less, 3.0 phr or less, 2.0 phr or less, or 1.0 phr or less.

In one or plurality of embodiments of this disclosure, one or both of terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

In one or plurality of embodiments of this disclosure, the aromatic polyamide comprising:

an aromatic polyamide having repeat units of general formulas (I) and (II):

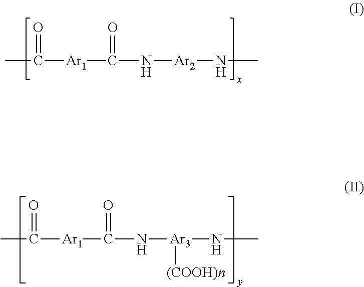

wherein x represents mole % of the repeat structure (I), y represents mole % of the repeat structure (II), x varies from 90 to 100, and y varies from 0 to 10;

wherein n=1 to 4;

wherein Ar₁ is selected from the group comprising:

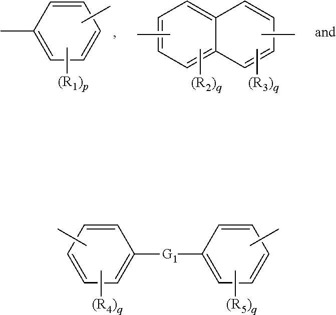

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

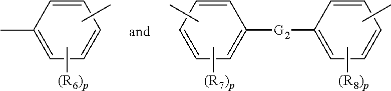

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylflorene;

wherein Ar₃ is selected from the group comprising:

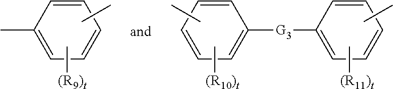

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

In one or plurality of embodiments of this disclosure, (I) and (II) are selected so that the polyamide is soluble in a polar solvent or a mixed solvent comprising one or more polar solvents. In one or plurality of embodiments of this disclosure, x varies from 90 to 100 mole % of the repeat structure (I), and y varies from 10 to 0 mole % of the repeat structure (II). In one or plurality of embodiments of this disclosure, the aromatic polyamide contains multiple repeat units with the structures (I) and (II) where Ar₁, Ar₂, and Ar₃ are the same or different.

In one or plurality of embodiments of this disclosure, in terms of enhancement of solubility of the polyamide to the solvent, the solvent is a polar solvent or a mixed solvent comprising one or more polar solvents. In one or plurality of embodiments of this disclosure, in terms of enhancement of solubility of the polyamide to the solvent, the solvent is an organic and/or an inorganic solvent. In one or plurality of embodiments of this disclosure, in terms of enhancement of solubility of the polyamide to the solvent and enhancement of the adhesion between polyamide film and the base, the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve, a combination thereof; or a mixed solvent comprising at least one of polar solvent thereof.

In one or plurality of embodiments of this disclosure, in terms of enhancement of the adhesion between polyamide film and the base, the aromatic polyamide is obtained or obtainable by a process comprising the steps of:

a) dissolving at least one aromatic diamine in a solvent;

b) reacting the at least one aromatic diamine mixture with at least one aromatic diacid dichloride, wherein hydrochloric acid and a polyamide solution is generated;

c) removing the free hydrochloric acid by reaction with a trapping reagent;

d) optionally adding a silane coupling agent.

In one or plurality of embodiments of this disclosure, in terms of enhancement of the adhesion between polyamide film and the base, one of the aromatic diamine selected from the group comprising 4,4′-diamino-2,2′-bistrifluoromethylbenzidine 9,9-bis(4-aminophenyl)fluorene, 9,9-bis(3-fluoro-4-aminophenyl)fluorene, 2,2′-bistrifluoromethoxylbenzidine, 4,4′-diamino-2,2′-bistrifluoromethyldiphenyl ether, bis-(4-amino-2-trifluoromethylphenyloxyl)benzene, and bis-(4-amino-2-trifluoromethylphenyloxyl)biphenyl with at least one aromatic diacid dichloride.

In one or plurality of embodiments of this disclosure, in terms of enhancement of the adhesion between polyamide film and the base, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

In one or plurality of embodiments of this disclosure, in terms of enhancement of the adhesion between polyamide film and the base, the solvent is a polar solvent or a mixed solvent comprising one or more polar solvents. In one or plurality of embodiments of this disclosure, the solvent is an organic and/or an inorganic solvent. In one or plurality of embodiments of this disclosure, in terms of enhancement of solubility of the polyamide to the solvent the and enhancement of the adhesion between polyamide film and the base, the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve, a combination thereof, or a mixed solvent comprising at least one of polar solvent thereof.

In one or plurality of embodiments of this disclosure, in terms of enhancement of the adhesion between polyamide film and the base, one of the diamine is 4,4′-diaminodiphenic acid or 3,5-diaminobenzoic acid.

In one or plurality of embodiments of this disclosure, in terms of enhancement of the adhesion between polyamide film and the base, the reaction of hydrochloric acid with the trapping reagent yields a volatile product.

In one or plurality of embodiments of this disclosure, in terms of enhancement of the adhesion between polyamide film and the base, the trapping reagent is propylene oxide. In one or plurality of embodiments of this disclosure, the trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, in terms of enhancement of heat resistance property of the polyamide film, the process further comprises the step of end-capping of one or both of terminal —COOH group and terminal —NH₂ group of the polyamide.

In one or plurality of embodiments of this disclosure, in terms of enhancement of the adhesion between polyamide film and the base, the polyamide is first isolated from the polyamide solution by precipitation and redissolved in a solvent prior to the addition of the silane coupling agent.

In one or plurality of embodiments of this disclosure, in terms of enhancement of the adhesion between polyamide film and the base, the solution is produced in the absence of inorganic salt.

Viewed from one aspect, this disclosure relates to a process for manufacturing a solution of an aromatic polyamide comprising the steps of:

a) dissolving at least one aromatic diamine in a solvent;

b) reacting the at least one aromatic diamine mixture with at least one aromatic diacid dichloride, wherein hydrochloric acid and a polyamide solution are generated;

c) removing the free hydrochloric acid by reaction with a trapping reagent;

d) adding a silane coupling agent.

In one or plurality of embodiments of this disclosure, in terms of enhancement of the adhesion between polyamide film and the base, and reducing the amount of the silane coupling agent to be added, the silane coupling agent has an amino group and/or an epoxy group. In one or plurality of embodiments of this disclosure, the silane coupling agent preferably has a methoxy and/or ethoxy group, in terms of enhancement of the adhesion between polyamide film and the base

In one or plurality of embodiments of this disclosure, the silane coupling agent includes, but is not limited to, Trimethoxy[2-(7-oxabicyclo[4.1.0]hept-3-yl)ethyl]silane, 3-Glycidoxypropylethyldimethoxysilane, 3-Glycidoxypropyltrimethoxysilane, 3-Glycidoxypropylmethyldiethoxysilane, 3-Glycidoxypropyltriethoxysilane, 3-(2-Aminoethylamino)propyl-dimethoxymethylsilane, 3-(2-Aminoethylamino)propyl-trimethoxysilane, 3-(Trimethoxysilyl)-1-propanamine, 3-(Triethoxysilyl)-1-propanamine, 3-triethoxysilyl-N-(1,3-dimethyl-butylidene)propylamine), N-[3-(Trimethoxysilyl)propyl]aniline, in terms of enhancement of the adhesion between polyamide film and the base.

In one or plurality of embodiments of this disclosure, concentration of silane coupling agent in the solution is, but is not limited to, 0.001 parts per hundred resins of polyamide (phr) or more, 0.01 phr or more, 0.1 phr or more, 0.3 phr or more, 0.4 phr or more, or 0.5 phr or more. In one or plurality of embodiments of this disclosure, concentration of silane coupling agent in the solution is, but is not limited to, 10.0 parts per hundred resins of polyamide (phr) or less, 5.0 phr or less, 3.0 phr or less, 2.0 phr or less, or 1.0 phr or less.

In one or plurality of embodiments of this disclosure, in terms of enhancement of the adhesion between polyamide film and the base, the aromatic diamine selected from the group comprising 4,4′-diamino-2,2′-bistrifluoromethylbenzidine 9,9-bis(4-aminophenyl)fluorene, 9,9-bis(3-fluoro-4-aminophenyl)fluorene, 2,2′-bistrifluoromethoxylbenzidine, 4,4′-diamino-2,2′-bistrifluoromethyldiphenyl ether, bis-(4-amino-2-trifluoromethylphenyloxyl)benzene, and bis-(4-amino-2-trifluoromethylphenyloxyl)biphenyl with at least one aromatic diacid dichloride.

In one or plurality of embodiments of this disclosure, in terms of enhancement of the adhesion between polyamide film and the base, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

In one or plurality of embodiments of this disclosure, in terms of enhancement of solubility of the polyamide to the solvent the adhesion between polyamide film and the base, the solvent is a polar solvent or a mixed solvent comprising one or more polar solvents. In one or plurality of embodiments of this disclosure, in terms of enhancement of the adhesion between polyamide film and the base, the solvent is an organic and/or an inorganic solvent. In one or plurality of embodiments of this disclosure, in terms of enhancement of solubility of the polyamide to the solvent the adhesion between polyamide film and the base and enhancement of the adhesion between polyamide film and the base, the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve, a combination thereof, or a mixed solvent comprising at least one of polar solvent thereof.

In one or plurality of embodiments of this disclosure, in terms of enhancement of the adhesion between polyamide film and the base, one of the diamine is 4,4′-diaminodiphenic acid or 3,5-diaminobenzoic acid.

In one or plurality of embodiments of this disclosure, the reaction of hydrochloric acid with the trapping reagent yields a volatile product.

In one or plurality of embodiments of this disclosure, in terms of enhancement of the adhesion between polyamide film and the base, the trapping reagent is propylene oxide. In one or plurality of embodiments of this disclosure, the trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, in terms of enhancement of heat resistance property of the polyamide film, the process further comprises the step of end-capping of one or both of terminal —COOH group and terminal —NH₂ group of the polyamide.

In one or plurality of embodiments of this disclosure, in terms of enhancement of the adhesion between polyamide film and the base, the polyamide is first isolated from the polyamide solution by precipitation and redissolved in a solvent prior to the addition of the silane coupling agent.

In one or plurality of embodiments of this disclosure, in terms of enhancement of the adhesion between polyamide film and the base, the solution is produced in the absence of inorganic salt.

In one or plurality of embodiments of this disclosure, in terms of enhancement of the adhesion between polyamide film and the base, the process is used for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film,

wherein the base or the surface of the base is composed of glass or silicon wafer.

Viewed from one aspect, this disclosure relates to a process for manufacturing a display element, an optical element or an illumination element (hereinafter, referred also to as “the process of the present disclosure”), comprising the steps of:

a) dissolving at least one aromatic diamine in a solvent;

b) reacting the at least one aromatic diamine mixture with at least one aromatic diacid dichloride, wherein hydrochloric acid and a polyamide solution are generated;

c) removing the free hydrochloric acid by reaction with a trapping reagent;

d) adding a silane coupling agent.

e) casting the resulting polyamide solution onto a base to form a polyamide film, wherein the base or the surface of the base is composed of glass or silicon wafer;

f) forming the display element, the optical element or the illumination element on the surface of the polyamide film.

In one or plurality of embodiments of this disclosure, in terms of enhancement of the adhesion between polyamide film and the base, and reducing the amount of the silane coupling agent to be added, the silane coupling agent has an amino group and/or an epoxy group. In one or plurality of embodiments of this disclosure, the silane coupling agent preferably has a methoxy and/or ethoxy group, in terms of enhancement of the adhesion between polyamide film and the base.

In one or plurality of embodiments of this disclosure, the silane coupling agent includes, but is not limited to, Trimethoxy[2-(7-oxabicyclo[4.1.0]hept-3-yl)ethyl]silane, 3-Glycidoxypropylethyldimethoxysilane, 3-Glycidoxypropyltrimethoxysilane, 3-Glycidoxypropylmethyldiethoxysilane, 3-Glycidoxypropyltriethoxysilane, 3-(2-Aminoethylamino)propyl-dimethoxymethylsilane, 3-(2-Aminoethylamino)propyl-trimethoxysilane, 3-(Trimethoxysilyl)-1-propanamine, 3-(Triethoxysilyl)-1-propanamine, 3-triethoxysilyl-N-(1,3-dimethyl-butylidene)propylamine), N-[3-(Trimethoxysilyl)propyl]aniline, in terms of enhancement of the adhesion between polyamide film and the base.

In one or plurality of embodiments of this disclosure, concentration of silane coupling agent in the solution is, but is not limited to, 0.001 parts per hundred resins of polyamide (phr) or more, 0.01 phr or more, 0.1 phr or more, 0.3 phr or more, 0.4 phr or more, or 0.5 phr or more. In one or plurality of embodiments of this disclosure, concentration of silane coupling agent in the solution is, but is not limited to, 10.0 parts per hundred resins of polyamide (phr) or less, 5.0 phr or less, 3.0 phr or less, 2.0 phr or less, or 1.0 phr or less.

In one or plurality of embodiments of this disclosure, in terms of enhancement of the adhesion between polyamide film and the base, one of the aromatic diamine selected from the group comprising 4,4′-diamino-2,2′-bistrifluoromethylbenzidine 9,9-bis(4-aminophenyl)fluorene, 9,9-bis(3-fluoro-4-aminophenyl)fluorene, 2,2′-bistrifluoromethoxylbenzidine, 4,4′-diamino-2,2′-bistrifluoromethyldiphenyl ether, bis-(4-amino-2-trifluoromethylphenyloxyl)benzene, and bis-(4-amino-2-trifluoromethylphenyloxyl)biphenyl with at least one aromatic diacid dichloride.

In one or plurality of embodiments of this disclosure, in terms of enhancement of the adhesion between polyamide film and the base, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

In one or plurality of embodiments of this disclosure, in terms of enhancement of solubility of the polyamide to the solvent, the solvent is a polar solvent or a mixed solvent comprising one or more polar solvents. In one or plurality of embodiments of this disclosure, the solvent is an organic and/or an inorganic solvent. In one or plurality of embodiments of this disclosure, in terms of enhancement of solubility of the polyamide to the solvent and enhancement of the adhesion between polyamide film and the base, the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve, a combination thereof, or a mixed solvent comprising at least one of polar solvent thereof.

In one or plurality of embodiments of this disclosure, in terms of enhancement of the adhesion between polyamide film and the base, one of the diamine is 4,4′-diaminodiphenic acid or 3,5-diaminobenzoic acid.

In one or plurality of embodiments of this disclosure, in terms of enhancement of the adhesion between polyamide film and the base, the reaction of hydrochloric acid with the trapping reagent yields a volatile product and the film is cast directly from the reaction mixture.

In one or plurality of embodiments of this disclosure, in terms of enhancement of the adhesion between polyamide film and the base, the trapping reagent is propylene oxide. In one or plurality of embodiments of this disclosure, the trapping reagent is added to the mixture before or during the reacting step (b). Adding the reagent before or during the reaction step (b) can reduce degree of viscosity and generation of lumps in the mixture after the reaction step (b), and therefore, can improve productivity of the solution of the polyamide. These effects are significant specifically when the reagent is organic reagent, such as propylene oxide.

In one or plurality of embodiments of this disclosure, in terms of enhancement of heat resistance property of the polyamide film, the process of the present disclosure further comprises the step of end-capping of one or both of terminal —COOH group and terminal —NH₂ group of the polyamide.

In one or plurality of embodiments of this disclosure, in terms of enhancement of the adhesion between polyamide film and the base, the polyamide is first isolated from the polyamide solution by precipitation and redissolved in a solvent prior to the addition of the silane coupling agent.

In one or plurality of embodiments of this disclosure, in terms of enhancement of the adhesion between polyamide film and the base, the film is produced in the absence of inorganic salt.

In one or plurality of embodiments of this disclosure, in terms of enhancement of the adhesion between polyamide film and the base, the process of the present disclosure, further comprising the step of:

g) de-bonding, from the base, the display element, the optical element or the illumination element formed on the base.

In one or plurality of embodiments of this disclosure, in terms of enhancement of the adhesion between polyamide film and the base, the step (b) further comprises heating the casted polyamide solution to form a polyamide film. In one or plurality of embodiments of this disclosure, in terms of enhancement of the adhesion between polyamide film and the base, the heating is carried out under the temperature ranging from approximately +40° C. of the boiling point of the solvent to approximately +100° C. of the boiling point of the solvent, preferably from approximately +60° C. of the boiling point of the solvent to approximately +80° C. of the boiling point of the solvent, more preferably approximately +70° C. of the boiling point of the solvent. In one or plurality of embodiments of this disclosure, in terms of enhancement of the adhesion between polyamide film and the base, the temperature of the heating in step (b) is between approximately 200° C. and approximately 250° C. In one or plurality of embodiments of this disclosure, in terms of enhancement of the adhesion between polyamide film and the base, the time of the heating is more than approximately 1 minute and less than approximately 30 minutes.

During the heating in the step (b), coupling reaction of the silane coupling agent occurs to render adhesion between the film and the base. Generally, coupling reaction between the organic group of the silane coupling agent and the polyamide occurs at 80° C. to 150° C., and generally, coupling reaction between the inorganic group of the silane coupling agent and the base (glass or silicon wafer) occurs at 60° C. to 150° C., and generally.

Viewed from one aspect, this disclosure relates to a process for manufacturing a display element, an optical element or an illumination element (hereinafter, referred also to as “the 2^{nd} process of the present disclosure”), comprising the steps of:

a) casting a solution of an aromatic polyamide into a film onto a base; and

b) forming the display element, the optical element or the illumination element on the surface of polyamide film;

wherein the solution of an aromatic polyamide comprising an aromatic polyamide, a solvent, and a silane coupling agent,

wherein the base or the surface of the base is composed of glass or silicon wafer.

In one or plurality of embodiments of this disclosure, in terms of enhancement of the adhesion between polyamide film and the base, and reducing the amount of the silane coupling agent to be added, the silane coupling agent has an amino group and/or an epoxy group. In one or plurality of embodiments of this disclosure, the silane coupling agent preferably has a methoxy and/or ethoxy group, in terms of enhancement of the adhesion between polyamide film and the base.

In one or plurality of embodiments of this disclosure, the silane coupling agent includes, but is not limited to, Trimethoxy[2-(7-oxabicyclo[4.1.0]hept-3-yl)ethyl]silane, 3-Glycidoxypropylethyldimethoxysilane, 3-Glycidoxypropyltrimethoxysilane, 3-Glycidoxypropylmethyldiethoxysilane, 3-Glycidoxypropyltriethoxysilane, 3-(2-Aminoethylamino)propyl-dimethoxymethylsilane, 3-(2-Aminoethylamino)propyl-trimethoxysilane, 3-(Trimethoxysilyl)-1-propanamine, 3-(Triethoxysilyl)-1-propanamine, 3-triethoxysilyl-N-(1,3-dimethyl-butylidene)propylamine), N-[3-(Trimethoxysilyl)propyl]aniline, in terms of enhancement of the adhesion between polyamide film and the base.

In one or plurality of embodiments of this disclosure, concentration of silane coupling agent in the solution is, but is not limited to, 0.001 parts per hundred resins of polyamide (phr) or more, 0.01 phr or more, 0.1 phr or more, 0.3 phr or more, 0.4 phr or more, or 0.5 phr or more. In one or plurality of embodiments of this disclosure, concentration of silane coupling agent in the solution is, but is not limited to, 10.0 parts per hundred resins of polyamide (phr) or less, 5.0 phr or less, 3.0 phr or less, 2.0 phr or less, or 1.0 phr or less.

In one or plurality of embodiments of this disclosure, in terms of enhancement of heat resistance property of the polyamide film, at least one of terminals of the aromatic polyamide is end-capped.

In one or plurality of embodiments of this disclosure, in terms of enhancement of heat resistance property of the polyamide film, the aromatic polyamide comprising:

an aromatic polyamide having repeat units of general formulas (I) and (II):

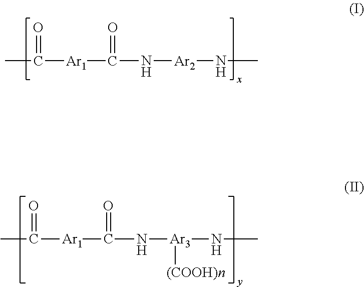

wherein x represents mole % of the repeat structure (I), y represents mole % of the repeat structure (II), x varies from 90 to 100, and y varies from 0 to 10;

wherein n=1 to 4;

wherein Ar₁ is selected from the group comprising:

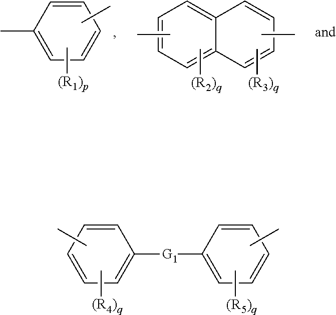

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

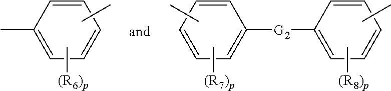

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylflorene;

wherein Ar₃ is selected from the group comprising:

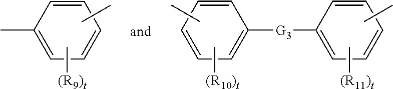

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group. 9,9-bisphenylfluorene group, and substituted 9,9-bisphenylfluorene.

In one or plurality of embodiments of this disclosure, in terms of enhancement of heat resistance property of the polyamide film, wherein (I) and (II) are selected so that the polyamide is soluble in a polar solvent or a mixed solvent comprising one or more polar solvents. In one or plurality of embodiments of this disclosure, in terms of enhancement of heat resistance property of the polyamide film, x varies from 90 to 100 mole % of the repeat structure (I), and y varies from 0 to 10 mole % of the repeat structure (II). In one or plurality of embodiments of this disclosure, in terms of enhancement of heat resistance property of the polyamide film, the aromatic polyamide contains multiple repeat units with the structures (I) and (II) where Ar₁, Ar₂, and Ar₃ are the same or different.

In one or plurality of embodiments of this disclosure, in terms of enhancement of solubility of the polyamide to the solvent, the solvent is a polar solvent or a mixed solvent comprising one or more polar solvents. In one or plurality of embodiments of this disclosure, in terms of enhancement of solubility of the polyamide to the solvent, the solvent is an organic and/or an inorganic solvent. In one or plurality of embodiments of this disclosure, in terms of enhancement of solubility of the polyamide to the solvent and enhancement of the adhesion between polyamide film and the base, the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve, a combination thereof, or a mixed solvent comprising at least one of polar solvent thereof.

In one or plurality of embodiments of this disclosure, in terms of enhancement of solubility of the polyamide to the solvent, the film is produced in the absence of inorganic salt.

In one or plurality of embodiments of this disclosure, the 2^{nd} process of the present disclosure further comprising the step of:

c) de-bonding, from the base, the display element, the optical element or the illumination element formed on the base.

In one or plurality of embodiments of this disclosure, in terms of enhancement of the adhesion between polyamide film and the base, the step (a) further comprises heating the casted polyamide solution to form a polyamide film. In one or plurality of embodiments of this disclosure, in terms of enhancement of the adhesion between polyamide film and the base, the heating is carried out under the temperature ranging from approximately +40° C. of the boiling point of the solvent to approximately +100° C. of the boiling point of the solvent, preferably from approximately +60° C. of the boiling point of the solvent to approximately +80° C. of the boiling point of the solvent, more preferably approximately +70° C. of the boiling point of the solvent. In one or plurality of embodiments of this disclosure, in terms of enhancement of the adhesion between polyamide film and the base, the temperature of the heating in step (a) is between approximately 200° C. and approximately 250° C. In one or plurality of embodiments of this disclosure, in terms of enhancement of the adhesion between polyamide film and the base, the time of the heating is more than approximately 1 minute and less than approximately 30 minutes.

During the heating in the step (b), coupling reaction of the silane coupling agent occurs to render adhesion between the film and the base. Generally, coupling reaction between the organic group of the silane coupling agent and the polyamide occurs at 80° C. to 150° C., and generally, coupling reaction between the inorganic group of the silane coupling agent and the base (glass or silicon wafer) occurs at 60° C. to 150° C., and generally.

In one or more embodiments, the aromatic diacid dichlorides used to polymerize the copolyamides are as shown in the following general structures:

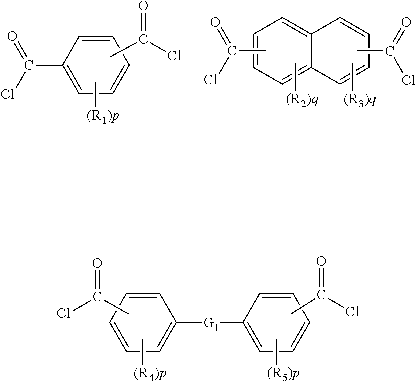

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

In one or more embodiments, the one or more aromatic diamines are as shown in the following general structures:

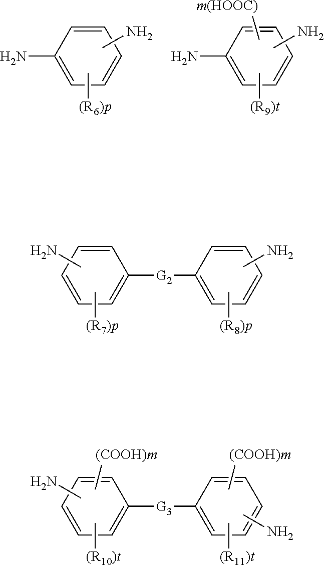

wherein p=4, m=1 or 2, and t=1 to 3, wherein R₆, R₇, R₈, R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₆ can be different, each R₇ can be different, each R₈ can be different, each R₉ can be different, each R₁₀ can be different, and each R₁₁ can be different. G₂ and G₃ are selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

This disclosure is directed toward solutions of aromatic copolyamides, and a display element, an optical element or an illumination element using the solutions and/or the films. A polyamide is prepared via a condensation polymerization in a solvent, where the hydrochloric acid generated in the reaction is trapped by a reagent like propylene oxide (PrO). The film can be made directly from the reaction mixture, without the need for isolating and re-dissolving the polyamide. Colorless films can be prepared by casting procedures directly from the polymerization solutions. The product of the reaction of the hydrochloric acid with the PrO is eliminated during the removal of the solvent. These films display low CTEs as cast and do not need to be subjected to stretching. By carefully manipulating the ratio of the monomers used to prepare the copolyamides, the CTEs and T_{g}s of the resulting copolymers and the optical properties of their solution cast films can be controlled. If the reaction of the reagent with the hydrochloric acid does not form volatile products, the polymer is isolated from the polymerization mixture by precipitation and re-dissolved by a polar solvent (without the need for inorganic salts) and cast in the film. If the reaction of the reagent with the hydrochloric acid does form volatile products, the film can be directly cast. One example, above, of a reagent that forms volatile products is PrO.

Representative and illustrative examples of the useful aromatic diacid dichlorides in the disclosure are:

Terephthaloyl dichloride (TPC);

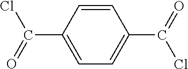 [SMILES: O=C(Cl)c1ccc(C(=O)Cl)cc1]

Isophthaloyl dichloride (IPC);

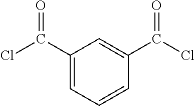 [SMILES: O=C(Cl)c1cccc(C(=O)Cl)c1]

2,6-Naphthaloyl dichloride (NDC);

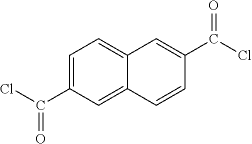 [SMILES: O=C(Cl)c1ccc2cc(C(=O)Cl)ccc2c1]

4,4′-Biphenyldicarbonyl dichloride (BPDC)

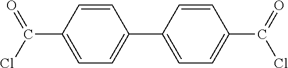 [SMILES: O=C(Cl)c1ccc(-c2ccc(C(=O)Cl)cc2)cc1]

Representative and illustrative examples of the useful aromatic diamines in the disclosure are:

4,4′-Diamino-2,2′-bistrifluoromethylbenzidine (PFMB)

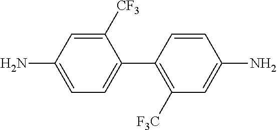 [SMILES: Nc1ccc(-c2ccc(N)cc2C(F)(F)F)c(C(F)(F)F)c1]

9,9-Bis(4-aminophenyl)fluorine (FDA)

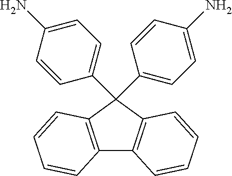 [SMILES: Nc1ccc(C2(c3ccc(N)cc3)c3ccccc3-c3ccccc32)cc1]

9,9-Bis(3-fluoro-4-aminophenyl)fluorine (FFDA)

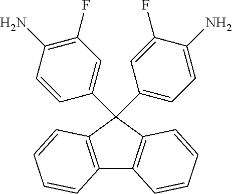 [SMILES: Nc1ccc(C2(c3ccc(N)c(F)c3)c3ccccc3-c3ccccc32)cc1F]

4,4′-Diaminodiphenic acid (DADP)

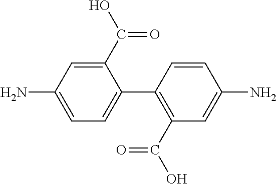 [SMILES: Nc1ccc(-c2ccc(N)cc2C(=O)O)c(C(=O)O)c1]

3,5-Diaminobenzoic acid (DAB)

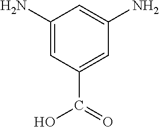 [SMILES: Nc1cc(N)cc(C(=O)O)c1]

4,4′-Diamino-2,2′-bistrifluoromethoxylbenzidine (PFMOB)

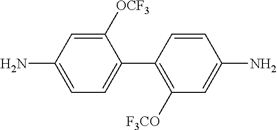 [SMILES: Nc1ccc(-c2ccc(N)cc2OC(F)(F)F)c(OC(F)(F)F)c1]

4,4′-Diamino-2,2′-bistrifluoromethyldiphenyl ether (6FODA)

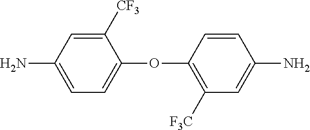 [SMILES: Nc1ccc(Oc2ccc(N)cc2C(F)(F)F)c(C(F)(F)F)c1]

Bis(4-amino-2-trifluoromethylphenyloxyl)benzene (6FOQDA)

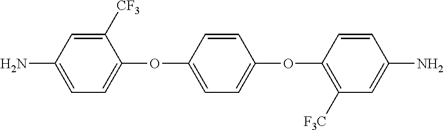 [SMILES: Nc1ccc(Oc2ccc(Oc3ccc(N)cc3C(F)(F)F)cc2)c(C(F)(F)F)c1]

Bis(4-amino-2-trifluoromethylphenyloxyl)biphenyl (6FOBDA)

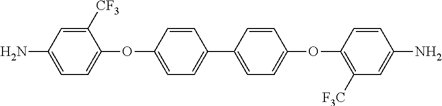 [SMILES: Nc1ccc(Oc2ccc(-c3ccc(Oc4ccc(N)cc4C(F)(F)F)cc3)cc2)c(C(F)(F)F)c1]

[Display Element, Optical Element, or Illumination Element]

The term “a display element, an optical element, or an illumination element” as used herein refers to an element that constitutes a display (display device), an optical device, or an illumination device, and examples of such elements include an organic EL element, a liquid crystal element, and organic EL illumination. Further, the term also covers a component of such elements, such as a thin film transistor (TFT) element, a color filter element or the like. In one or more embodiments, the display element, the optical element or the illumination element according to the present disclosure may include the polyamide film according to the present disclosure, may be produced using the solution of polyamide according to the present disclosure, or may use the polyamide film according to the present disclosure as the substrate of the display element, the optical element or the illumination element.

<Non-Limiting Embodiment of Organic EL Element>

Hereinafter, one embodiment of an organic EL element as one embodiment of the display element according to the present disclosure will be described with reference to the drawing.

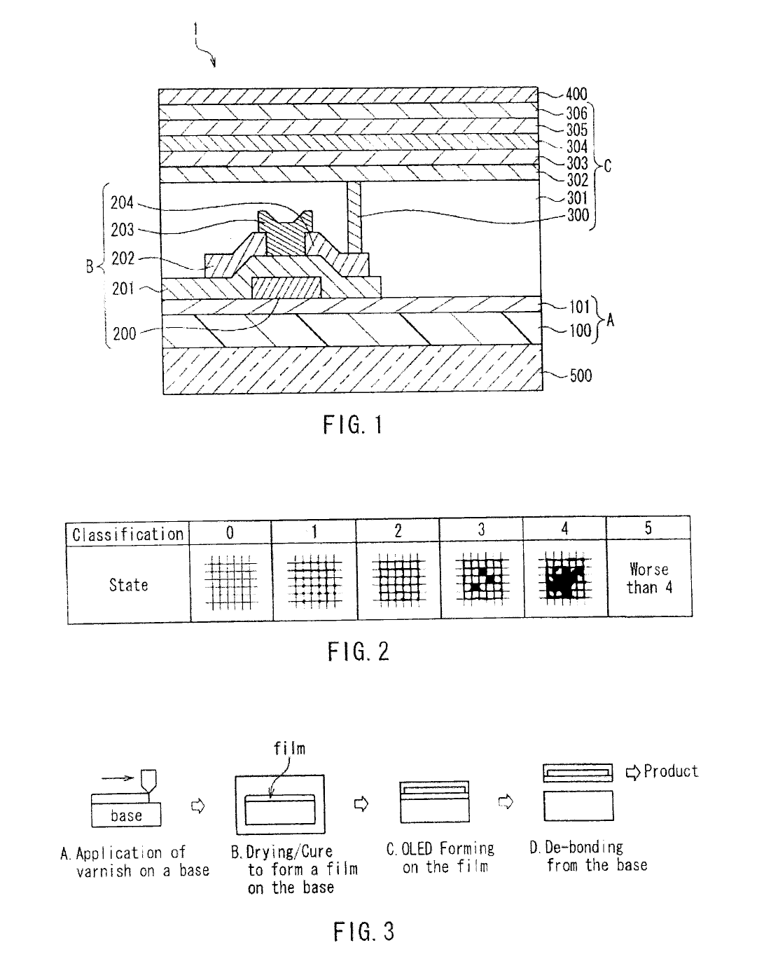

FIG. 1 is a schematic cross-sectional view showing an organic EL element 1 according to one embodiment. The organic EL element 1 includes a thin film transistor B formed on a substrate A and an organic EL layer C. Note that the organic EL element 1 is entirely covered with a sealing member 400. The organic EL element 1 may be separate from a base 500 or may include the base 500. Hereinafter, each component will be described in detail.

1. Substrate A

The substrate A includes a transparent resin substrate 100 and a gas barrier layer 101 formed on top of the transparent resin substrate 100. Here, the transparent resin substrate 100 is the polyamide film according to the present disclosure.

The transparent resin substrate 100 may have been annealed by heat. Annealing is effective in, for example, removing distortions and in improving the size stability against environmental changes.

The gas barrier layer 101 is a thin film made of SiOx, SiNx or the like, and is formed by a vacuum deposition method such as sputtering, CVD, vacuum deposition or the like. Generally, the gas barrier layer 101 has a thickness of, but is not limited to, about 10 nm to 100 nm. Here, the gas barrier layer 101 may be formed on the side of the transparent resin substrate 100 facing the gas barrier layer 101 in FIG. 1 or may be formed on the both sides of the transparent resin substrate 100.

2. Thin Film Transistor

The thin film transistor B includes a gate electrode 200, a gate insulating layer 201, a source electrode 202, an active layer 203, and a drain electrode 204. The thin film transistor 13 is formed on the gas barrier layer 101.

The gate electrode 200, the source electrode 202, and the drain electrode 204 are transparent thin films made of indium tin oxide (ITO), indium zinc oxide (IZO), zinc oxide (ZnO), or the like. For example, sputtering, vapor deposition, ion platting or the like may be use to form these transparent thin films. Generally, these electrodes have a film thickness of, but is not limited to, about 50 nm to 200 nm.

The gate insulating film 201 is a transparent insulating thin film made of SiO₂, Al₂O₃ or the like, and is formed by sputtering, CVD, vacuum deposition, ion plating or the like. Generally, the gate insulating film 201 has a film thickness of, but is not limited to, about 10 nm to 1 μm.

The active layer 203 is a layer of, for example, single crystal silicon, low temperature polysilicon, amorphous silicon, or oxide semiconductor, and a material best suited to the active layer 203 is used as appropriate. The active layer is formed by sputtering or the like.

3. Organic EL Layer

The organic EL layer C includes a conductive connector 300, an insulative flattened layer 301, a lower electrode 302 as the anode of the organic EL element A, a hole transport layer 303, a light-emitting layer 304, an electron transport layer 305, and an upper electrode 306 as the cathode of the organic EL element A. The organic EL layer C is formed at least on the gas barrier layer 101 or on the thin film transistor B, and the lower electrode 302 and the drain electrode 204 of the thin film transistor B are connected to each other electrically through the connector 300. Instead, the lower electrode 302 of the thin film transistor B and the source electrode 202 may be connected to each other through the connector 300.

The lower electrode 302 is the anode of the organic EL element 1a, and is a transparent thin film made of indium tin oxide (ITO), indium zinc oxide (IZO), zinc oxide (ZnO) or the like. ITO is preferred because, for example, high transparency, and high conductivity can be achieved.

For the hole transport layer 303, the light-emitting layer 304, and the electron transport layer 305, conventionally-known materials for organic EL elements can be used as is.

The upper electrode 305 is a film composed of a layer of lithium fluoride (LiF) having a film thickness of 5 nm to 20 nm and a layer of aluminum (Al) having a film thickness of 50 nm to 200 nm. For example, vapor deposition may be use to form the film.

When producing a bottom emission type organic EL element, the upper electrode 306 of the organic EL element 1a may be configured to have optical reflectivity. Thereby, the upper electrode 306 can reflect in the display side direction light generated by the organic EL element A and traveled toward the upper side as the opposite direction to the display side. Since the reflected light is also utilized for a display purpose, the emission efficiency of the organic EL element can be improved.

[Method of Producing Display Element, Optical Element, or Illumination Element]

Another aspect of the present disclosure relates to a method of producing a display element, an optical element, or an illumination element. In one or more embodiments, the production method according to the present disclosure is a method of producing the display element, the optical element, or the illumination element according to the present disclosure. Further, in one or more embodiments, the production method according to the present disclosure is a method of producing a display element, an optical element, or an illumination element, which includes the steps of: applying the polyamide resin composition according to the present disclosure onto a base; forming a polyamide film after the application step; and forming the display element, the optical element, or the illumination element on the side of the base not in contact with the polyamide resin film. The production method according to the present disclosure may further include the step of de-bonding, from the base, the display element, the optical element, or the illumination element formed on the base.

<Non-Limiting Embodiment of Method of Producing Organic EL Element>

As one embodiment of the method of producing a display element according in the present disclosure, hereinafter, one embodiment of a method of producing an organic EL element will be described with reference to the drawing.

A method of producing the organic EL element 1 shown in FIG. 1 includes a fixing step, a gas barrier layer preparation step, a thin film transistor preparation step, an organic EL layer preparation step, a sealing step and a de-bonding step. Hereinafter, each step will be described in detail.

1. Fixing Step

In the fixing step, the transparent resin substrate 100 is fixed onto the base 500. A way to fix the transparent resin substrate 100 to the base 500 is not particularly limited. For example, an adhesive may be applied between the base 500 and the transparent substrate or a part of the transparent resin substrate 100 may be fused and attached to the base 500 to fix the transparent resin substrate 100 to the base 500. Further, as the material of the base, glass, metal, silicon, resin or the like is used, for example. These materials may be used alone or in combination of two or more as appropriate. Furthermore, the transparent resin substrate 100 may be attached to the base 500 by applying a releasing agent or the like to the base 500 and placing the transparent resin substrate 100 on the applied releasing agent. In one or more embodiments, the polyamide film 100 is formed by applying the polyamide resin composition according to the present disclosure to the base 500, and drying the applied polyamide resin composition.

2. Gas Barrier Layer Preparation Step

In the gas barrier layer preparation step, the gas barrier layer 101 is prepared on the transparent resin substrate 100. A way to prepare the gas barrier layer 101 is not particularly limited, and a known method can be used.

3. Thin Film Transistor Preparation Step

In the thin film transistor preparation step, the thin film transistor B is prepared on the gas barrier layer. A way to prepare the thin film transistor B is not particularly limited, and a known method can be used.

4. Organic EL Layer Preparation Step

The organic EL layer preparation step includes a first step and a second step. In the first step, the flattened layer 301 is formed. The flattened layer 301 can be formed by, for example, spin-coating, slit-coating, or ink-jetting a photosensitive transparent resin. At that time, an opening needs to be formed in the flattened layer 301 so that the connector 300 can be formed in the second step. Generally, the flattened layer has a film thickness of, but is not limited to, about 100 nm to 2 μm.

In the second step, first, the connector 300 and the lower electrode 302 are formed at the same time. Sputtering, vapor deposition, ion platting or the like may be used to form the connector 300 and the lower electrode 302. Generally, these electrodes have a film thickness of, but is not limited to, about 50 nm to 200 nm. Subsequently, the hole transport layer 303, the light-emitting layer 304, the electron transport layer 305, and the upper electrode 306 as the cathode of the organic EL element A are formed. To form these components, a method such as vapor deposition, application, or the like can be used as appropriate in accordance with the materials to be used and the laminate structure. Further, irrespective of the explanations given in this example, other layers may be chosen from known organic layers such as a hole injection layer, an electron transport layer, a hole blocking layer and an electron blocking layer as needed and be used to configuring the organic layers of the organic EL element A.

5. Sealing Step

In the sealing step, the organic EL layer A is sealed with the sealing member 307 from top of the upper electrode 306. For example, a glass material, a resin material, a ceramics material, a metal material, a metal compound or a composite thereof can be used to form the sealing member 307, and a material best suited to the sealing member 307 can be chosen as appropriate.

6. De-Bonding Step

In the de-bonding step, the organic EL element 1 prepared is stripped from the base 500. To implement the de-bonding step, for example, the organic EL element 1 may be physically stripped from the base 500. At that time, the base 500 may be provided with a de-bonding layer, or a wire may be inserted between the base 500 and the display element to remove the organic EL element. Further, examples of other methods of de-bonding the organic EL element 1 from the base 500 include the following: forming a de-bonding layer on the base 500 except at ends, and cutting, after the preparation of the element, the inner part from the ends to remove the element from the base; providing a layer of silicon or the like between the base 500 and the element, and irradiating the silicon layer with a laser to strip the element; applying heat to the base 500 to separate the base 500 and the transparent substrate from each other; and removing the base 500 using a solvent. These methods may be used alone or any of these methods may be used in combination of two or more. Especially in one or more embodiments, the strength of adhesion between PA film and the Base can be controlled by silane coupling agent, so that the organic EL element 1 may be physically stripped without using the complicated process such as described above.

In one or more embodiments, the organic EL element obtained by the method of producing a display, optical or illumination element according to the present embodiment has excellent characteristics such as excellent transparency and heat-resistance, low linear expansivity and low optical anisotropy.

[Display Device, Optical Device, and Illumination Device]

Another aspect of the present disclosure relates to a display device, an optical device, or an illumination device using the display element, the optical element, or the illumination element according to the present disclosure, or a method of producing the display device, the optical device, or the illumination device. Examples of the display device include, but are not limited to, an imaging element, examples of the optical device include, but are not limited to, a photoelectric complex circuit, and examples of the illumination device include, but are not limited to, a TFT-LCD and OEL illumination.

This disclosure may relate to any of the following.

[a1] A solution of polyamide comprising:

an aromatic polyamide, a silane coupling agent and a solvent.

[a2] The solution according to [a1] for use in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film,

wherein the base or the surface of the base is composed of glass or silicon wafer.

[a3] The solution according to [a1] or [a2], wherein the silane coupling agent has an amino group and/or an epoxy group.
[a4] The solution according to any one of [a1] to [a3], wherein the silane coupling agent has a methoxy and/or ethoxy group.
[a5] The solution according to any one of [a1] to [a4] wherein at least one of terminals of the aromatic polyamide is end-capped.
[a6] The solution according to any one of [a1] to [a5], wherein the aromatic polyamide comprising:

an aromatic polyamide having repeat units of general formulas (I) and (II):

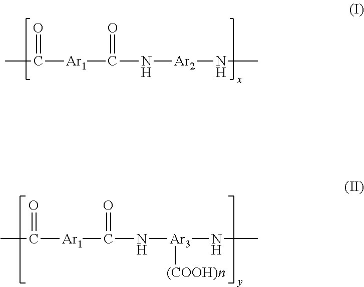

wherein x represents mole % of the repeat structure (I), y represents mole % of the repeat structure (II), x varies from 90 to 100, and y varies from 0 to 10;

wherein n=1 to 4;

wherein Ar₁ is selected from the group comprising:

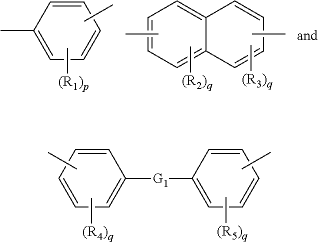

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

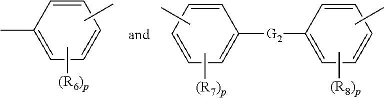

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylflorene;

wherein Ar₃ is selected from the group comprising:

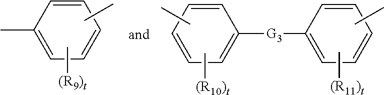

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

[a7] The solution according to [a6], wherein (I) and (II) are selected so that the polyimide is soluble in a polar solvent or a mixed solvent comprising one or more polar solvents.
[a8] The solution according to [a6] or [a7], wherein x varies from 90 to 100 mole % of the repeat structure (I), and y varies from 0 to 10 mole % of the repeat structure (II).
[a9] The solution according to any one of [a6] to [a8], wherein the aromatic polyamide contains multiple repeat units with the structures (I) and (II) where Ar₁, Ar₂, and Ar₃ are the same or different.
[a10] The solution according to any one of [a1] to [a9], wherein the solvent is a polar solvent or a mixed solvent comprising one or more polar solvents.
[a11] The solution according to any one of [a1] to [a10], wherein the solvent is an organic and/or an inorganic solvent.
[a12] The solution according to any one of [a1] to [a11], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[a13] The solution according to any one of [a1] to [a12], wherein the aromatic polyamide is obtained by a process comprising the steps of:

a) dissolving at least one aromatic diamine in a solvent;

b) reacting the at least one aromatic diamine mixture with at least one aromatic diacid dichloride, wherein hydrochloric acid and a polyamide solution is generated;

c) removing the free hydrochloric acid by reaction with a trapping reagent;

d) adding a silane coupling agent.

[a14] The solution according to [a13], wherein one of the aromatic diamine selected from the group comprising 4,4′-diamino-2,2′-bistrifluoromethylbenzidine 9,9-bis(4-aminophenyl)fluorene, 9,9-bis(3-fluoro-4-aminophenyl)fluorene, 2,2′-bistrifluoromethoxylbenzidine, 4,4′-diamino-2,2′-bistrifluoromethyldiphenyl ether, bis-(4-amino-2-trifluoromethylphenyloxyl)benzene, and bis-(4-amino-2-trifluoromethylphenyloxyl)biphenyl with at least one aromatic diacid dichloride.
[a15] The solution according to [a13] or [a14], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[a16] The solution according to any one of [a13] to [a15] wherein the solvent is a polar solvent or a mixed solvent comprising one or more polar solvents.
[a17] The solution according to any one of [a13] to [a16], wherein the solvent is an organic and/or an inorganic solvent.
[a18] The solution according to any one of [a13] to [a17], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[a19] The solution according to any one of [a13] to [a18], wherein one of the diamine is 4,4′-diaminodiphenic acid or 3,5-diaminobenzoic acid.
[a20] The solution according to any one of [a1] to [a19], wherein the reaction of hydrochloric acid with the trapping reagent yields a volatile product.
[a21] The solution according to any one of [a13] to [a20], wherein the trapping reagent is propylene oxide.
[a22] The solution according to any one of [a13] to [a23], wherein the trapping reagent is added to the mixture before or during the reacting step (b).
[a23] The solution according to any one of [a13] to [a22], wherein the process further comprises the step of end-capping of one or both of terminal —COOH group and terminal —NH₂ group of the polyamide.
[a24] The solution according to any one of [a13] to [a23], wherein the polyamide is first isolated from the polyamide solution by precipitation and redissolved in a solvent prior to the addition of the silane coupling agent.
[a25] The solution according to any one of [a13] to [a24], wherein the solution is produced in the absence of inorganic salt.
[b1]A process for manufacturing a solution of an aromatic polyamide comprising the steps of:

a) dissolving at least one aromatic diamine in a solvent;

b) reacting the at least one aromatic diamine mixture with at least one aromatic diacid dichloride, wherein hydrochloric acid and a polyamide solution are generated;

c) removing the free hydrochloric acid by reaction with a trapping reagent;

d) adding a silane coupling agent.

[b2] The process according to [b1], wherein the silane coupling agent has an amino group and/or an epoxy group.
[b3] The process according to [b1] or [b2], wherein the silane coupling agent has a methoxy and/or ethoxy group.
[b4] The process according to one of [b1] to [b3], wherein one of the aromatic diamine selected from the group comprising 4,4′-diamino-2,2′-bistrifluoromethylbenzidine 9,9-bis(4-aminophenyl) fluorene, 9,9-bis(3-fluoro-4-aminophenyl)fluorene, 2,2′-bistrifluoromethoxylbenzidine, 4,4′-diamino-2,2′-bistrifluoromethyldiphenyl ether, bis-(4-amino-2-trifluoromethylphenyloxyl)benzene, and bis-(4-amino-2-trifluoromethylphenyloxyl) biphenyl with at least one aromatic diacid dichloride.
[b5] The process according to one of [b1] to [b4], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[b6] The process according to any one of [b1] to [b5], wherein the solvent is a polar solvent or a mixed solvent comprising one or more polar solvents.
[b7] The process according to any one of [b1] to [b6], wherein the solvent is an organic and/or an inorganic solvent.
[b8] The process according to any one of [b1] to [b7], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[b9] The process according to any one of [b1] to [b8], wherein one of the diamine is 4,4′-diaminodiphenic acid or 3,5-diaminobenzoic acid.
[b10] The solution according to any one of [b1] to [b9], wherein the reaction of hydrochloric acid with the trapping reagent yields a volatile product.
[b11] The process according to any one of [b1] to [b10], wherein the trapping reagent is propylene oxide.
[b12] The process according to any one of [b1] to [b11], wherein the trapping reagent is added to the mixture before or during the reacting step (b).
[b13] The process according to any one of [b1] to [b12], wherein the process further comprises the step of end-capping of one or both of terminal —COOH group and terminal —NH₂ group of the polyamide.
[b14] The process according to any one of [b1] to [b13], wherein the polyamide is first isolated from the polyamide solution by precipitation and redissolved in a solvent prior to the addition of the silane coupling agent.
[b15] The process according to any one of [b1] to [b14], wherein the solution is produced in the absence of inorganic salt.
[b16] The process according to one of [b1] to [b15] for use in the process for manufacturing a display element, an optical element or an illumination element, comprising the steps of:

a) applying a solution of an aromatic polyamide onto a base;

b) forming a polyamide film on the base after the applying step (a); and

c) forming the display element, the optical element or the illumination element on the surface of polyamide film,

wherein the base or the surface of the base is composed of glass or silicon wafer.

[c1] A process for manufacturing a display element, an optical element or an illumination element, comprising the steps of:

a) dissolving at least one aromatic diamine in a solvent;

b) reacting the at least one aromatic diamine mixture with at least one aromatic diacid dichloride, wherein hydrochloric acid and a polyamide solution are generated;

c) removing the free hydrochloric acid by reaction with a trapping reagent;

d) adding a silane coupling agent.

e) casting the resulting polyamide solution onto a base to form a polyamide film, wherein the base or the surface of the base is composed of glass or silicon wafer;

f) forming the display element, the optical element or the illumination element on the surface of the polyamide film.

[c2] The process according to [c1], wherein the silane coupling agent has an amino group and/or an epoxy group.
[c3] The process according to claim 1 or 2, wherein the silane coupling agent has a methoxy and/or ethoxy group.
[c4] The process according to any one of [c1] to [c3], wherein one of the aromatic diamine selected from the group comprising 4,4′-diamino-2,2′-bistrifluoromethylbenzidine 9,9-bis(4-aminophenyl)fluorene, 9,9-bis(3-fluoro-4-aminophenyl)fluorene, 2,2′-bistrifluoromethoxylbenzidine, 4,4′-diamino-2,2′-bistrifluoromethyldiphenyl ether, bis-(4-amino-2-trifluoromethylphenyloxyl)benzene, and bis-(4-amino-2-trifluoromethylphenyloxyl) biphenyl with at least one aromatic diacid dichloride.
[c5] The process according to any one of [c1] to [c4], wherein the at least one aromatic diacid dichloride is selected from the group comprising terephthaloyl dichloride, isophthaloyl dichloride, 2,6-naphthaloyl dichloride, and 4,4,-biphenyldicarbonyl dichloride.
[c6] The process according to any one of [c1] to [c5], wherein the solvent is a polar solvent or a mixed solvent comprising one or more polar solvents.
[c7] The process according to any one of [c1] to [c6], wherein the solvent is an organic and/or an inorganic solvent.
[c8] The process according to any one of [c1] to [c7], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof, or a mixed solvent comprising at least one of polar solvent thereof.
[c9] The process according to any one of [c1] to [c8], wherein one of the diamine is 4,4′-diaminodiphenic acid or 3,5-diaminobenzoic acid.
[c10] The solution according to any one of [c1] to [c9], wherein the reaction of hydrochloric acid with the trapping reagent yields a volatile product and the film is cast directly from the reaction mixture.
[c11] The process according to [c10], wherein the trapping reagent is propylene oxide.
[c12]. The process according to any one of [c1] to [c11], wherein the trapping reagent is added to the mixture before or during the reacting step (b).
[c13] The process according to any one of [c1] to [c12], wherein the process further comprises the step of end-capping of one or both of terminal —COOH group and terminal —NH₂ group of the polyamide.
[c14] The process according to any one of [c1] to [c13], wherein the polyamide is first isolated from the polyamide solution by precipitation and redissolved in a solvent prior to the addition of the silane coupling agent.
[c15] The process according to any one of [c1] to [c14], wherein the film is produced in the absence of inorganic salt.
[c16] The process according to any one of [c1] to [c15], further comprising the step of:

g) de-bonding, from the base, the display element, the optical element or the illumination element formed on the base.

[c17] The process according to any one of [c1] to [c16], wherein the step (b) further comprises heating the casted polyamide solution to form a polyamide film, wherein the heating is carried out under the temperature ranging from approximately +40° C. of the boiling point of the solvent to approximately +100° C. of the boiling point of the solvent.
[c18] The process according to [c17], wherein the temperature of the heating in step (b) is between approximately 200° C. and approximately 250° C.
[c19] The process according to [c1] or [c18], wherein the time of the heating is more than approximately 1 minute and less than approximately 30 minutes.
[d1] A process for manufacturing a display element, an optical element or an illumination element, comprising the steps of:

a) casting a solution of an aromatic polyamide into a film onto a base; and

b) forming the display element, the optical element or the illumination element on the surface of polyamide film;

wherein the solution of an aromatic polyamide comprising an aromatic polyamide, a solvent, and a silane coupling agent,

wherein the base or the surface of the base is composed of glass or silicon wafer.

[d2] The process according to [d1], wherein the silane coupling agent has an amino group and/or an epoxy group.
[d3] The process according to [d1] or [d2], wherein the silane coupling agent has a methoxy and/or ethoxy group.
[d4] The process according to one of [d1] to [d3], wherein at least one of terminals of the aromatic polyamide is end-capped.
[d5] The process according to any one of [d1] to [d4], wherein the aromatic polyamide comprising:

an aromatic polyamide having repeat units of general formulas (I) and (II):

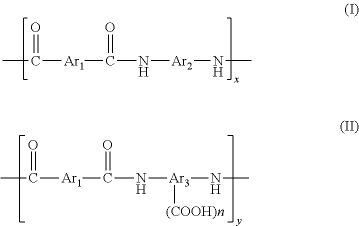

wherein x represents mole % of the repeat structure (I), y represents mole % of the repeat structure (II), x varies from 90 to 100, and y varies from 0 to 10;

wherein n=1 to 4;

wherein Ar₁ is selected from the group comprising:

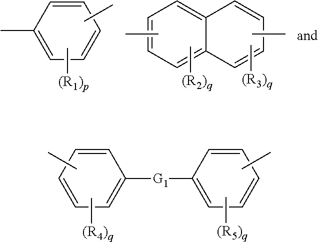

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;

wherein Ar₂ is selected from the group of comprising:

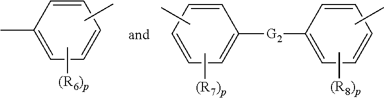

wherein p=1, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylflorene;

wherein Ar₃ is selected from the group comprising:

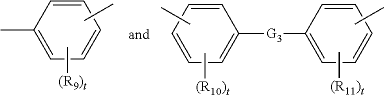

wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

[d6] The process according to [d5], wherein (I) and (II) are selected so that the polyamide is soluble in a polar solvent or a mixed solvent comprising one or more polar solvents.
[d7] The process according to [d5] or [d6], wherein x varies from 90 to 100 mole % of the repeat structure (I), and y varies from 0 to 10 mole % of the repeat structure (II).
[d8] The process according to any one of [d5] to [d7], wherein the aromatic polyamide contains multiple repeat units with the structures (I) and (II) where Ar₁, Ar₂, and Ar₃ are the same or different.
[d9] The process according to any one of [d1] to [d8], wherein the solvent is a polar solvent or a mixed solvent comprising one or more polar solvents.
[d10] The process according to any one of [d1] to [d9], wherein the solvent is an organic and/or an inorganic solvent.
[d11] The process according to any one of [d1] to [d10], wherein the solvent is cresol, N,N-dimethylacetamide (DMAc), N-methyl-2-pyrrolidinone (NMP), dimethylsulfoxide (DMSO), butyl cellosolve (BCS), or a mixed solvent comprising at least one of cresol, N,N-dimethylacetamide (DMAc), N-methyl-2-pyrrolidinone (NMP), dimethylsulfoxide (DMSO), 1,3-dimethyl-imidazolidinone (DMI), or butyl cellosolve (BCS), a combination thereof; or a mixed solvent comprising at least one of polar solvent thereof.
[d12] The process according to any one of [d1] to [d11], wherein the film is produced in the absence of inorganic salt.
[d13] The process according to any one of [d1] to [d12], further comprising the step of:

c) de-bonding, from the base, the display element, the optical element or the illumination element formed on the base.

[d14] The process according to any one of [d1] to [d13], wherein the step (a) further comprises heating the casted polyamide solution to form a polyamide film, wherein the heating is carried out under the temperature ranging from approximately +40° C. of the boiling point of the solvent to approximately +100° C. of the boiling point of the solvent.
[d15] The process according to [d14], wherein the temperature of the heating in step (a) is between approximately 200° C. and approximately 250° C.
[d16] The process according to [d14] or [d15], wherein the time of the heating is more than approximately 1 minute and less than approximately 30 minutes.

### EXAMPLES

Polyamide solutions (Solution 1 to 8) were prepared using components as described in Table 1 as well as bellow

[Aromatic Diamine]

PFMB: 4,4′-Diamino-2,2′-bistrifluoromethylbenzidine

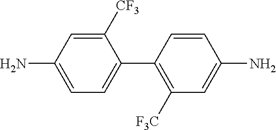 [SMILES: Nc1ccc(-c2ccc(N)cc2C(F)(F)F)c(C(F)(F)F)c1]

DAB: 4,4′-diaminobenzoic acid

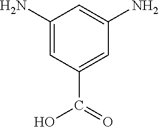 [SMILES: Nc1cc(N)cc(C(=O)O)c1]

[Solvent]

### DMAc: N,N-dimethylacetamide

### BCS: Butylcellosolve

[Aromatic Diacid Dichloride]

IPC: Isophthaloyl dichloride

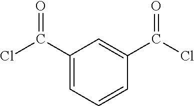 [SMILES: O=C(Cl)c1cccc(C(=O)Cl)c1]

TPC: Terephaloyl dichloride

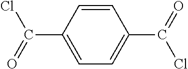 [SMILES: O=C(Cl)c1ccc(C(=O)Cl)cc1]

[Silane Coupling Agent]

3-(Trimethoxysilyl)-1-propanamine: (C₂H₅O)₃SiC₃H₆NH₂ (trade name: KBM903, Shin-Etsu Chemical Co, Ltd.)

[Trapping Reagent]

PrO: propylene oxide

Specifically, Solutions 3 and 7 were prepared as described below;

Solution 3: To a 250 ml three necked round bottom flask, equipped with a mechanical stirrer, a nitrogen inlet and outlet, are added PFMB (3.2024 g, 0.01 mol) and dried DMAc (45 ml). After the PFMB dissolved completely, PrO (1.4 g, 0.024 mol) was added to the solution. The solution is cooled to 0° C. Under stirring, IPC (1.0049 g 0.00495 mol) was added to the solution, and the flask wall was washed with DMAc (1.5 ml). After 15 minutes, TPC (1.0049 g, 0.00495 mol) was added to the solution and the flask wall was again washed with DMAc (1.5 ml). After two hours, benzoyl chloride (0.030 g, 0.216 mmol) was added to the solution and stirred for another two hours to obtain Solution 3.

Solution 7: To a 250 ml three necked round bottom flask, equipped with a mechanical stirrer, a nitrogen inlet and outlet, are added PFMB (3.042 g, 0.0095 mol), DAB (0.0761 g, 0.0005 mol) DMAc (27 ml) and BCS (18 ml). After the PFMB dissolved completely, PrO (1.4 g, 0.024 mol) was added to the solution. The solution is cooled to 0° C. Under stirring, IPC (1.0049 g, 0.00495 mol) was added to the solution, and the flask wall was washed with DMAc (9 ml) and BCS (6 ml). After 15 minutes, TPC (1.0049 g, 0.00495 mol) was added to the solution and the flask wall was again washed with DMAc (0.9 ml) and BCS (0.6 ml). After two hours, benzoyl chloride (0.030 g, 0.216 mmol) was added to the solution and stirred for another two hours to obtain Solution 7.

Polyamide films are prepared by use of Solutions 1 to 8 on a surface of a glass base. Adhesions between the films and the glass base were measured by “Tape Test” (JIS K5600-5-6/ISO 2409) as described below. The results are estimated by the classification described in FIG. 2. The results are shown in the Table 1.

[Film Formation]

The polymer solution can be used directly for the film casting after polymerization. For the preparation of small films in a batch process, the solution is poured on a flat glass plate, EAGLE XG (Corning Inc., U.S.A.). After drying on the substrate, under reduced pressure, at 60° C. for several hours, the film is further dried at 200° C. under protection of dry nitrogen flow for 1 hour. The film is cured by heating at or near the polymer T_{g} under vacuum or in an inert atmosphere for several minutes. Thickness of films were greater than approximately 10 μm thick.

[Adhesion Tape Test]

All of the tools (multiplex edge, tape), and way of tests were measured according to JIS K5600-5-6/ISO 2409 test. The film was cut into 25 measures with the multiplex edge. After that, film peeling test was used by adhesive tape, KT-SP3007 TQC ISO-Adhesive Tape (COTEC CO., LTD., Japan). Toughness of adhesion was estimated by the classification described in FIG. 2.

TABLE 1

| | Component | | | | |
|---|---|---|---|---|---|
| | | | | Silane | Adhesion |
| | | | | Coupling | Test |
| | | | Diacid | Agent | Classi- |
| Table 1 | Diamine | Solvent | Dichloride | (phr*) | fication |
| Solution 1 | PFMB | DMAc | IPC/TPC | 0.0 | 5 |
| | | | (50/50, | | |
| | | | molar | | |
| | | | ratio) | | |
| Solution 2 | PFMB | DMAc | IPC/TPC | 0.1 | 3 |
| | | | (50/50, | | |
| | | | molar | | |
| | | | ratio) | | |
| Solution 3 | PFMB | DMAc | IPC/TPC | 0.5 | 0 |
| | | | (50/50, | | |
| | | | molar | | |
| | | | ratio) | | |
| Solution 4 | PFMB | DMAc | IPC/TPC | 1.0 | 0 |
| | | | (50/50, | | |
| | | | molar | | |
| | | | ratio) | | |
| Solution 5 | PFMB/DAB | DMAc/ | IPC/TPC | 0.0 | 5 |
| | (95/5, | BCS | (50/50, | | |
| | molar | (60/40 by | molar | | |
| | ratio) | weight) | ratio) | | |
| Solution 6 | PFMB/DAB | DMAc/ | IPC/TPC | 0.1 | 3 |
| | (95/5, | BCS | (50/50, | | |
| | molar | (60/40 by | molar | | |
| | ratio) | weight) | ratio) | | |
| Solution 7 | PFMB/DAB | DMAc/ | IPC/TPC | 0.5 | 0 |
| | (95/5, | BCS | (50/50, | | |
| | molar | (60/40 by | molar | | |
| | ratio) | weight) | ratio) | | |
| Solution 8 | PFMB/DAB | DMAc/ | IPC/TPC | 1.0 | 0 |
| | (95/5, | BCS | (50/50, | | |
| | molar | (60/40 by | molar | | |
| | ratio) | weight) | ratio) | | |

*“phr” represents “parts per hundred resins”

As shown in Table 1, adhesions between polyamide film and the glass base of Solutions 2 to 4, and Solutions 6-8 are significantly improved by compared with Solutions 1 and 5, respectively.

The embodiments have been described, hereinabove. It will be apparent to those skilled in the art that the above methods and apparatuses may incorporate changes and modifications without departing from the general scope of this disclosure. It is intended to include all such modifications and alterations insofar as they come within the scope of the appended claims or the equivalents thereof. Although the description above contains much specificity, this should not be construed as limiting the scope of the disclosure, but as merely providing illustrations of some of the embodiments of this disclosure. Various other embodiments and ramifications are possible within its scope.

Furthermore, notwithstanding that the numerical ranges and parameters setting forth the broad scope of the disclosure are approximations, the numerical values set forth in the specific examples are reported as precisely as possible. Any numerical value, however, inherently contain certain errors necessarily resulting from the standard deviation found in their respective testing measurements.

What is claimed is:

1. A solution of polyamide comprising:
an aromatic polyamide, silane coupling agent and a solvent.

2. The solution according to claim 1 for use in the process for manufacturing a display element, an optical element or an illumination element, comprising the steps of:
a) applying a solution of an aromatic polyamide onto a base;
b) forming a polyamide film on the base after the applying step (a); and
c) forming the display element, the optical element or the illumination element on the surface of polyamide film,
wherein the base or the surface of the base is composed of glass or silicon wafer.

3. The solution according to claim 1, wherein the silane coupling agent has an amino group and/or an epoxy group.

4. The solution according to claim 1, wherein the silane coupling agent has a methoxy and/or ethoxy group.

5. The solution according to claim 1, wherein the aromatic polyamide comprising:
an aromatic polyamide having repeat units of general formulas (I) and (II): 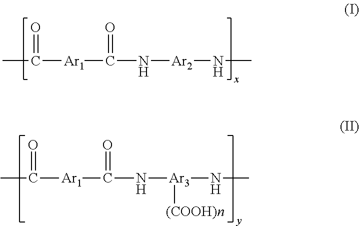
wherein x represents mole % of the repeat structure (I), y represents mole % of the repeat structure (II), x varies from 90 to 100, and y varies from 0 to 10;
wherein n=1 to 4;
wherein Ar₁ is selected from the group comprising: 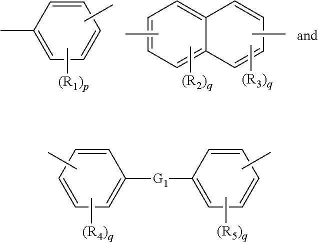
wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, wherein G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene;
wherein Ar₂ is selected from the group of comprising: 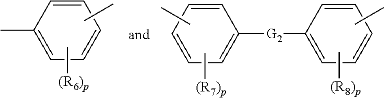
wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylflorene;
wherein Ar₃ is selected from the group comprising: 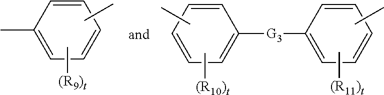
wherein t=2 or 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, wherein G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si(CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

6. The solution according to claim 5, wherein (I) and (II) are selected so that the polyamide is soluble in a polar solvent or a mixed solvent comprising one or more polar solvents.

7. The solution according to claim 5, wherein x varies from 90 to 100 mole % of the repeat structure (I), and y varies from 0 to 10 mole % of the repeat structure (II).

8. The solution according to claim 5, wherein the aromatic polyamide contains multiple repeat units with the structures (I) and (II) where Ar₁, Ar₂, and Ar₃ are the same or different.

9. The solution according to claim 1, wherein the aromatic polyamide is obtained by a process comprising the steps of:
a) dissolving at least one aromatic diamine in a solvent;
b) reacting the at least one aromatic diamine mixture with at least one aromatic diacid dichloride, wherein hydrochloric acid and a polyamide solution is generated;
c) removing the free hydrochloric acid by reaction with a trapping reagent;
d) adding a silane coupling agent.

10. The solution according to claim 9, wherein one of the diamine is 4,4′-diaminodiphenic acid or 3,5-diaminobenzoic acid.

11. A process for manufacturing a display element, an optical element or an illumination element, comprising the steps of:
a) dissolving at least one aromatic diamine in a solvent;
b) reacting the at least one aromatic diamine mixture with at least one aromatic diacid dichloride, wherein hydrochloric acid and a polyamide solution are generated;
c) removing the free hydrochloric acid by reaction with a trapping reagent;
d) adding a silane coupling agent.
e) casting the resulting polyamide solution onto a base to form a polyamide film, wherein the base or the surface of the base is composed of glass or silicon wafer;
f) forming the display element, the optical element or the illumination element on the surface of the polyamide film.

12. The process according to claim 11, further comprising the step of:
g) de-bonding, from the base, the display element, the optical element or the illumination element formed on the base.
